(19) United States
(12) Patent Application Publication
(10) Pub. No.: US 2025/0140522 A1
(43) Pub. Date: May 1, 2025

(54) SEMICONDUCTOR PROCESS APPARATUS AND METHOD

(71) Applicant: Taiwan Semiconductor Manufacturing Company LTD, Hsinchu (TW)

(72) Inventors: Chun-Wei Cheng, Tainan (TW); Kai Fu Chuang, Tainan (TW); Yi-Ming Lin, Tainan (TW); Kuo-Chiang Chen, Tainan (TW); Chih-Chen Chao, Tainan (TW); Ting-Cheng Chen, Tainan (TW)

(21) Appl. No.: 18/384,253

(22) Filed: Oct. 26, 2023

(51) Int. Cl. H01J 37/317

(52) U.S. Cl. CPC H01J 37/3171; H01J 2237/006; H01J 2237/24585

(57) ABSTRACT

A process gas is flowed from an input metal gas line that is electrically grounded to an output metal gas line via a connecting tube which is electrically insulating. Couplings between the metal gas lines and the connecting tube are sealed with gas couplings. Each gas coupling includes a sealing gasket, and a clamp compressing the sealing gasket between an end of the respective metal gas line and a corresponding end of the connecting tube. The process gas is delivered to a semiconductor processing tool via the output metal gas line. At least one operation is performed at the semiconductor processing tool that utilizes both the process gas delivered to the process tool via the output metal gas line and an electrical voltage of at least 2 kilovolts. The connecting tube may be sapphire. The sealing gaskets may be polytetrafluoroethylene (PTFE) sealing gaskets.

### BACKGROUND

The following relates to the semiconductor processing arts, ion implantation arts, high voltage arts, toxic gas handling arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a semiconductor processing system.

FIGS. 2 and 3 diagrammatically illustrate perspective views of the gas interface of the semiconductor processing system of FIG. 1.

FIG. 4 diagrammatically illustrates an isolation view of the connecting tube, with sectional views of the input and output gas couplings.

FIGS. 5 and 6 diagrammatically show perspective views of an embodiment of the output gas coupling of FIG. 4, shown without the fasteners (FIG. 5), and further without the first clamp piece (FIG. 6).

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Ion implantation is widely used in the semiconductor processing arts, for example to form doped regions with high spatial precision and controlled doping level. For example, ion implantation can be used to form the buried doped layer of a deep p-type well (DPW) or deep n-type well (DNW) with well-defined depth and thickness. For n-type doping of silicon via ion implantation, arsine (AsH₃) or phosphine (PH₃) can be used as process gases for providing arsenic (As) or phosphorous (P) dopants, respectively. In another application, a silicon-on-insulator (SOI) wafer can be formed by the SIMOX method, where a high dosage of oxygen atoms is implanted at a controlled depth and thickness followed by annealing to convert the implanted oxygen layer to silicon dioxide (SiO₂). These are merely some nonlimiting illustrative applications.

An ion implantation tool includes an ion source which receives the process gas (e.g., arsine or phosphine for n-type doping applications) and ionizes the gas using a heated filament and applied voltage, for example, and accelerates the generated ions toward the target (e.g., a silicon wafer). Magnetic and electrostatic fields can be employed to perform functions such as mass separation to select the ion species for use in the implantation, and ion beam forming and steering to enable scanning or otherwise control the spatial extent of the implanted region or regions. Ion energy can be controlled by the accelerator voltage, and the ion energy has a significant impact on the implantation depth. Flow rate of the process gas, and implantation time, are some further settings that can control characteristics such as the doping level.

While ion implanters are commonplace in semiconductor fabrication facilities (i.e., semiconductor fabs), they present some safety challenges. Many process gases used in ion implantation are highly toxic. For example, arsine has a medial lethal concentration (LC₅₀) on the order of 80-200 ppm (parts-per-million) depending on the experimental non-human species, and industrial safety regulations typically impose a limit which is under 10 ppm. Phosphine has similarly high toxicity. The process gas handling requirements for such toxic gases are stringent, for example requiring use of self-contained breathing apparatus (SCBA) during installation or changeout of process gas bottles, deployment of a continuously operating gas monitoring system, scheduled leak checking of gas valves and connectors, dedicated and specialized fittings for gas lines and valves and frequent leak checking of the fittings and valves, gas scrubbers appropriate for the type(s) of process gases used, employee safety training including establishment of evacuation procedures, specialized training for emergency response personnel, and so forth.

In addition to safety concerns posed by the frequent utilization of toxic gases such as arsine or phosphine, an ion implanter also generates high voltages, such as for the ion accelerator component. The ion implanter may operate at a high voltage of 60-80 kV (kilovolts), or even higher in some cases. Thus, the ion implanter presents an electrical shock hazard for personnel.

The combined usage of toxic process gas(es) and high electrical voltages in operation of an ion implanter presents further safety challenges. The gas handling system for toxic gases such as arsine or phosphine typically employs stainless steel or other metal tubing or piping for the gas lines, as polymer or plastic tubing is insufficiently leak tight and too prone to damage to be permissible for use in handling such toxic gases. Metal gas fittings are also used to ensure against process gas leakage. The gas supply cabinet containing the arsine, phosphine, or other process gas bottles, as well as the downstream gas lines, electrically grounded to protect against electrostatic discharge (ESD) events. This means the metal gas lines are at electrical ground (0 kV). By contrast, the ion implanter tool can be at a much higher voltage, e.g., 60-80 kV in some cases.

In addition to the foregoing safety concerns, seismic resistance can be yet a further safety consideration. A large magnitude earthquake or forces from a typhoon can have the potential to disrupt or break gas fittings, introducing gas leakage which is particularly problematic if the gas in question is a toxic gas such as arsine or phosphine.

While the foregoing safety context is described with particular reference to ion implanter systems, similar issues can arise in other types of semiconductor processing tools that employ a combination of gas input (especially, but not limited to, toxic gases) and high electrical voltages. As some further examples, some types of plasma deposition systems and plasma etching systems may employ high voltages in converting source or etchant gas to plasma, and hence these types of semiconductor processing tools can similarly utilize high voltage and also receive process gas(es) from an electrically grounded process gas supply.

Disclosed herein are semiconductor process apparatus embodiments that provide improved gas handling to enable safe delivery of a gas or gases to a semiconductor processing tool that employs high voltage. Also disclosed herein are gas supply boxes that are interposed between the gas supply cabinet and the ion implanter or other high voltage semiconductor processing tool, in which the gas supply box has an electrically insulating housing and one or more rigid, gas-tight, and electrically insulating tubes, such as one or more sapphire tubes, for gas coupling between an electrically grounded process gas line and the high voltage semiconductor processing tool. Also disclosed herein are gas fittings to connect the sapphire (or other rigid, gas-tight, and electrically insulating tube) with metal gas lines on the electrically grounded and high voltage sides. A gas supply box in accord with embodiments disclosed herein provides advantages such as enabling gas coupling across the ground-to-high voltage transition, providing for easy engagement and disengagement of the gas couplings for maintenance, compatibility with a continuously operating gas monitoring system including the ability to apply positive pressure to the gas supply box, and good seismic resistance.

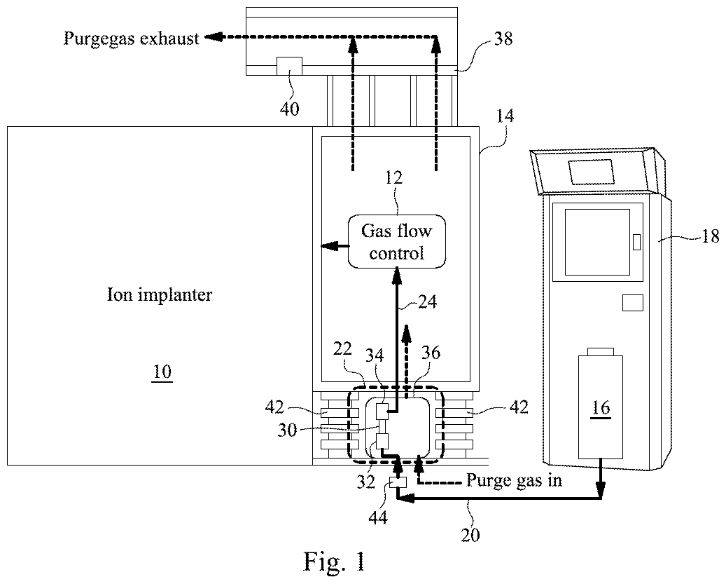

With reference to FIG. 1, a semiconductor processing system includes a semiconductor processing tool 10 (illustrative ion implanter 10) configured to operate at a high voltage, for example at least 20 kV (kilovolts) in some embodiments, or at least 60 kV in some embodiments, or at least 80 kV in some embodiments, or still higher voltages in some embodiments. In the case of the illustrative ion implanter 10, the high voltage operation or operations may include operations such as energizing an electrostatic accelerator to accelerate ions of a process gas to produce high energy ions for implantation into a silicon layer or wafer or other target for purposes such as dopant implantation, formation of the insulator layer of a silicon-on-insulator (SOI) wafer, or so forth. Gas flow control 12 in the form of pneumatically and/or electrically actuated valves, pneumatically and/or electrically operated mass flow controllers (MFC's), and/or so forth, are operated by an electronic ion implanter controller (not shown) to control flow of process gas to the semiconductor processing tool 10 in accordance with a process recipe or schedule. In some illustrative embodiments, the process gas may be a toxic gas such as arsine or phosphine, and the gas flow control 12 is installed in a gas box 14 to provide containment and early detection (to be described) of any process gas leak. The process gas is typically supplied in bottles (also known as gas cylinders), such as an illustrative gas bottle 16 disposed in a gas supply cabinet 18. Other types of process gas supply are contemplated, such as a bubbler fed by a carrier gas such as nitrogen or argon. The illustrative gas bottle 16 is typically connected with a regulator to control flow of the process gas out of the bottle 16, and for toxic process gases the supply cabinet 18 typically includes safety features such as a continuously operating gas monitoring system, and may be electrically grounded to protect against electrostatic discharge (ESD) events. An input metal gas line 20 connects from the gas bottle 16 to a gas interface 22 that interfaces to an output metal gas line 24 that delivers the process gas to the semiconductor processing tool 10 (and more particularly to the gas flow controller 12 thereof).

In operation, as noted the ion implanter 10 performs at least one operation that utilizes a high electrical voltage, e.g. at least 20 kV in some embodiments. As the output metal gas line 24 is electrically conductive, this means the output metal gas line 24 is at high voltage (HV), e.g. at least 20 kV in some embodiments or, at least, potentially could be at high voltage if an electrical malfunction were to occur in the implanter 10. On the other hand, the input metal gas line 20 connects with the gas bottle 16 in the gas supply cabinet 18, and is at electrical ground potential (0 volts). The gas interface 22 includes features providing robust electrical isolation of the input metal gas line 20 from the output metal gas line 24, while also ensuring safe flow transfer of the process gas (which as previously noted could be a toxic gas such as arsine or phosphine) from the input metal gas line 20 to the output metal gas line 24. To this end, the gas connection from the input metal gas line 20 to the output metal gas line 24 is via a connecting tube 30 which is both electrically insulating and mechanically rigid. An input gas coupling 32 provides a gas-tight seal between an end of the input metal gas line 20 and a first end of the connecting tube 30, and an output gas coupling 34 provides a gas-tight seal between an end of the output metal gas line 24 and a second end of the connecting tube 30. Furthermore, the gas interface 22 includes a housing 36 which is electrically insulating, and the connecting tube 30, the input gas coupling 32, and the output gas coupling 34 are disposed within the housing 36.

With continuing reference to FIG. 1, in some embodiments a purge gas flows through the housing 36 of the gas interface 22, with the housing being leak tight or close to leak tight (some leakage of purge gas may be acceptable). The purge gas flows through the housing 36 of the gas interface 22 and through the gas box 14 of the ion implanter 10 to an overhead purge gas exhaust 38. The purge gas is not a process gas used in the semiconductor processing performed by the ion implanter or other semiconductor processing tool 10; rather, the purge gas has a safety function, and is used to contain and facilitate detection of any leak of the process gas. The purge gas may be nitrogen (N₂) gas or another inert gas, for example. The gas flow control 12 (e.g., pneumatically and/or electrically operated valves, MFCs, et cetera) is disposed in the gas box 14 which is also leak tight or close to leak tight and through which the purge gas flows (again, some leakage of purge gas may be acceptable). A leak of the process gas is most likely to occur at a valve, MFC, gas coupling, or the like (as opposed to leaking through a continuous metal gas line), and hence continuous monitoring of the gas interface 22 and gas flow control 12 is important, especially when the process gas is toxic. In the semiconductor processing system of FIG. 1, the purge gas flows generally upward through the housing 36 of the gas interface 22 and through the gas box 14 containing the gas flow control 12 and into the purge gas exhaust 38. A continuously operating gas monitor system sensor 40 is disposed in the purge gas exhaust 38 to detect the presence of the toxic gas in the purge gas flowing through the purge gas exhaust 38. For example, the gas monitor system sensor 40 could be a sensor of a multi-point toxic gas monitoring system, e.g. an MDA Scientific toxic gas monitor for detecting arsine and/or phosphine at very low concentrations (e.g., on the order of parts-per-million, ppm). Although not shown, the gas monitor system could optionally include additional sensors located in other places such as inside the housing 36 of the gas interface 22, inside the gas box 14, and/or inside the ion implanter 10.

As an example, as previously noted the process gas arsine sometimes used as an n-type dopant source for doping of silicon by ion implantation has a medial lethal concentration (LC₅₀) on the order of 80-200 ppm (parts-per-million), and industrial safety regulations typically impose a limit which is under 10 ppm. Due to confinement of the flow of the purge gas through the housing 36 of the gas interface 22 and the gas box 14 of the ion implanter 10, the concentration of leaking arsine that would enter the ambient air of the workspace occupied by personnel is much less than the concentration of arsine in the purge gas flowing through the housing 36 and gas box 14. Furthermore, detection of arsine in the purge gas exhaust by the sensor 40 provides early detection of an arsine leak in a gas coupling of the gas interface 22, or an arsine leak in a valve, MFC, or other component of the gas flow control 12. In a typical safety configuration, detection by the sensor 40 of arsine above a (typically very low) concentration threshold automatically triggers a shutoff valve (not shown) located near the gas bottle 16 (e.g., inside the gas supply cabinet 18, for example just downstream of the regulator connected to the bottle 16), and also activates an emergency evacuation alert system including flashing warning lights and an audible evacuation alert to ensure personnel safely evacuate the area until the arsine leak can be located and repaired.

In the illustrative example of FIG. 1, the gas interface 22 is disposed between supports 42 of the gas box 14 of the ion implanter 10. These supports 30 may be electrically insulating to facilitate electrical isolation of the gas box 14, and the illustrative supports 30 include stress relief features to provide good seismic resistance in the event of an earthquake, typhoon, or other potential source of vibrational disturbance. Placement of the gas interface 22 within the supports 42 advantageously protects the gas interface 22 from inadvertent contact with personnel working around the ion implanter 10. An optional restrictive flow orifice (RFO) 44 may be provided to control flow of the process gas to the gas interface 22.

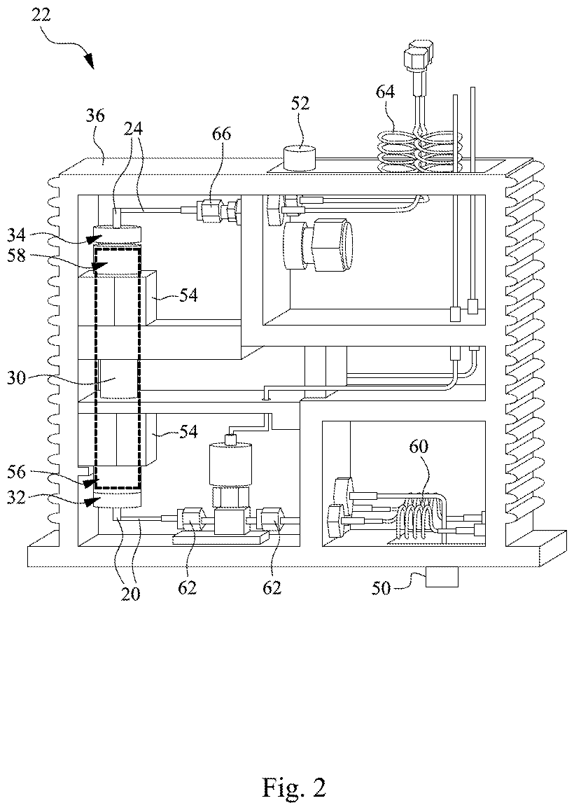

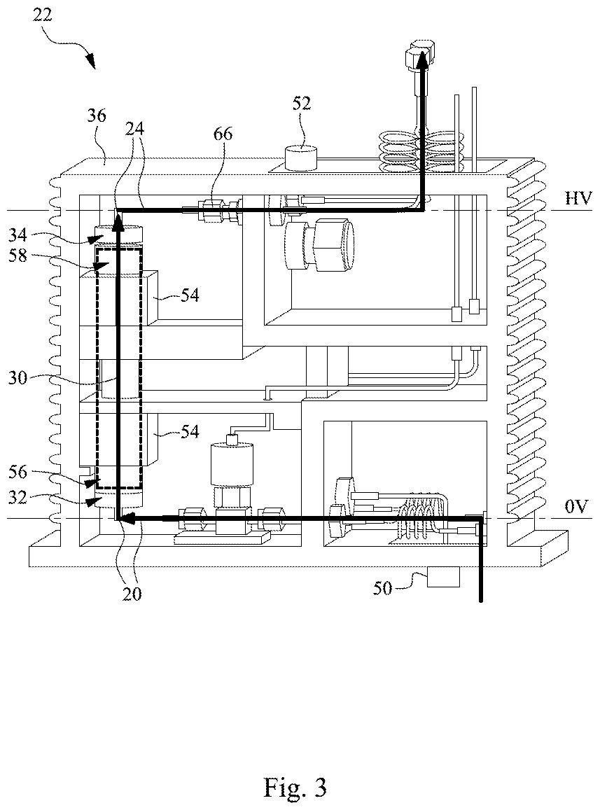

With reference now to FIGS. 2 and 3, the gas interface 22 is described in further detail. The gas interface 22 is shown in diagrammatic perspective view in FIG. 2, and the same perspective view is shown in FIG. 3 with the flow path of the process gas and the ground and HV indicated by horizontal dashed lines. The illustrative gas box includes the housing 36, which is suitably made of an electrically insulating material such as a hard plastic material. The housing 36 is a structural component and hence should be a rigid body (e.g., hard plastic). Note that the housing 36 is typically a fully (or almost fully) enclosed structure to contain the purge gas flowing therethrough; however, FIGS. 1-3 depict the housing 36 without front and back panels in order to reveal internal components. A purge gas inlet 50 disposed at a lower end (e.g., bottom or floor) of the housing 36 provides for flow of the purge gas into the housing 36, and a purge gas outlet 52 disposed at an upper end (e.g., top) of the housing 36 provides for flow of the purge gas out of the housing 36. With brief reference back to FIG. 1, the purge gas outlet 52 may connect with a purge gas inlet (not shown) of the gas box 14 of the semiconductor processing tool 10 to enable the purge gas to flow from the housing 36 into the gas box 14 and thence into the purge gas exhaust 38. The connecting tube 30 is securely held inside the housing 36 by clamps or other fasteners 54. In this way, the assembly of the housing 36 and connecting tube 30 form a rigid assembly which assist in making the gas interface 22 earthquake resistant. The connecting tube 30 has a first end 56 and a second end 58. In the illustrative example, the connecting tube 30 is oriented vertically with the first end 56 near to the bottom of the housing 36 where the input metal gas line 20 is located, and the second end 58 near to the top of the housing 36 where the output metal gas line 24 is located.

As best seen in FIG. 2, the nonlimiting illustrative embodiment of the input metal gas line 20 (which is normally at electrical ground or 0V potential as diagrammatically indicated in FIG. 3) includes multiple components. These include a gas tube coil 60 providing seismic stress relief (again furthering earthquake resistance of the gas interface 22) and various tube couplings 62 (labeled only in FIG. 2). The input gas coupling 32 provides a gas-tight seal between an end of the input metal gas line 20 and the first end 56 of the connecting tube 30. The output metal gas line 24 is at the high voltage (HV), or at least could accidentally be at the high voltage if there is an accidental electrical short, shunt, or other malfunction of a HV component of the semiconductor processing system 10 (such as a short of the electrostatic accelerator of the illustrative ion implanter 10 which may operate at the electrical HV of at least 2 kilovolts, or in some embodiments 60-80 kV or higher). The nonlimiting illustrative embodiment of the output metal gas line 24 also includes multiple components, such as a gas tube coil 64 providing seismic stress relief (again furthering earthquake resistance of the gas interface 22) and various tube couplings 66 (labeled only in FIG. 2).

More generally, the input metal gas line 20 and the output metal gas line 24 may in general be any suitable metal gas line, such as a tube or pipe of stainless steel as one nonlimiting illustrative example. Each metal gas line 20 and 24 may be a single tube or pipe, or may include two or more tube or pipe segments which are interconnected by one or more suitable leak-tight gas couplings. Each metal gas line 20 and 24 may optionally incorporate one or more components such as a flowmeter, a pressure sensor, a filter, in-line valve(s), and/or so forth.

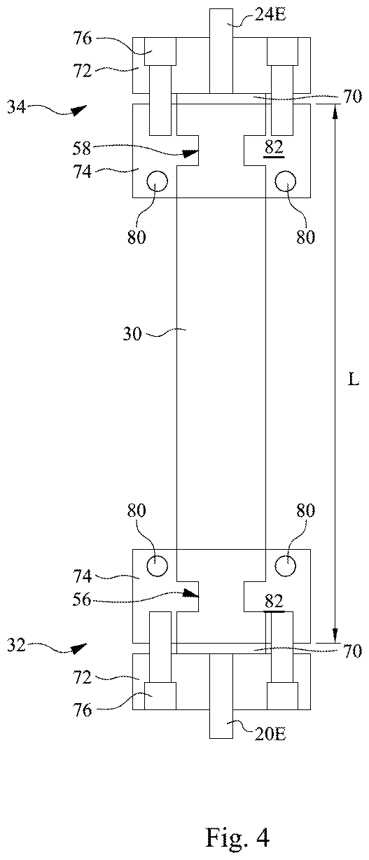

With reference now to FIG. 4, an isolation view is shown of the connecting tube 30, with sectional views of the input and output gas couplings 32 and 34. The input gas coupling 32 connects the first end 56 of the connecting tube 30 and an end 20E of the input metal gas line 20. The output gas coupling 34 connects the second end 58 of the connecting tube 30 and an end 24E of the output metal gas line 24. The input gas coupling 32 and the output gas coupling 34 have the same construction in the illustrative example, and accordingly, like reference numbers are used to label like components of the two gas couplings 32 and 34.

The connecting tube 30 is made of an electrically insulating material, and is rigid to provide seismic resistance. The illustrative connecting tube 30 is a single-piece tube, which advantageously avoids seams or joints that could pose locations of leakage of the process gas. In illustrative examples herein, the connecting tube 30 is a sapphire tube, where the term “sapphire” as used herein encompasses both natural and synthetic sapphire; said another way, the connecting tube comprises aluminum oxide (Al₂O₃) in a single crystal structure. Sapphire advantageously is a hard material. For example, synthetic sapphire has a Vickers hardness of about 15-17 GPa and a Mohs hardness of about 9. Sapphire also has high electrical resistivity, e.g. on the order of 10¹⁶ ohm-cm at room temperature in some embodiments. Other types of hard and electrically insulating materials are also contemplated for use as the connecting tube 30.

The illustrative connecting tube 30 is a straight tube having a length L as indicated in FIG. 4. The length L of the connecting tube 30 should be a length sufficient to ensure enough spacing between the end 56 of the connecting tube 30 and the second end 58 of the connecting tube 30 to avoid electrical arcing or other electrical shunting or shorting between the (at least possible) HV at the second end 58 and the ground potential (0V) at the first end 56. The minimum value for the length L of the connecting tube 30 to achieve this desired electrical isolation principally depends on the magnitude of the HV (or possible HV) at the output metal gas line 24. In general, the minimum length will increase to provide sufficient isolation as the maximum HV (or possible HV) on the output metal gas line 24 increases. In some nonlimiting illustrative embodiments, the length L of the connecting tube is at least 15 cm to provide the desired electrical isolation; and in some embodiments (e.g., for higher HV) a longer minimum tube length of 20 cm or longer is desirable.

Each of the input gas coupling 32 and the output gas coupling 34 includes a sealing gasket 70. Thus, the input gas coupling 32 includes a sealing gasket 70 disposed between the end 20E of the input metal gas line 20 and the first end 56 of the connecting tube 30; and the output gas coupling 34 includes a sealing gasket 70 disposed between the end 22E of the output metal gas line 24 and the second end 58 of the connecting tube 30. A compression clamp provides compression of the sealing gasket 70 to ensure a gas tight seal. In the illustrative example, a first clamp piece 72 engages the end 20E of the input metal gas line 20, and a second clamp piece 74 engages the first end 56 of the connecting tube 30. The first and second clamp pieces 72 and 74 are secured together by fasteners 76 (e.g., illustrative bolts, or screws or another type of fasteners) to draw the end 20E of the input metal gas line 20 and the first end 56 of the connecting tube 30 together to thereby compress the sealing gasket 70 between the end 20E of the input metal gas line 20 and the first end 56 of the connecting tube 30. Likewise, a first clamp piece 72 engages the end 24E of the output metal gas line 24, and a second clamp piece 74 engages the second end 58 of the connecting tube 30. The first and second clamp pieces 72 and 74 are secured together by fasteners 76 (e.g., illustrative bolts, or screws or another type of fasteners) to draw the end 24E of the output metal gas line 24 and the second end 58 of the connecting tube 30 together to thereby compress the sealing gasket 70 between the end 24E of the output metal gas line 24 and the second end 58 of the connecting tube 30.

The sealing gaskets 70 may in some nonlimiting illustrative embodiments be polytetrafluoroethylene (PTFE) gaskets 70. PTFE is advantageously a softer material than the sapphire of the connecting tube 30, e.g., PTFE has a Vickers hardness on the order of about 30-50 MPa (compared with about 15-17 GPa for sapphire). Thus, the gaskets 70 can be compressed against the ends 56 and 58 of the sapphire connecting tube 30, without damaging the end 56 and 58, to provide the desired gas tight seal. In some embodiments, the PTFE gaskets 70 may be made of Teflon™ (a particular brand of PTFE). Instead of PTFE, the sealing gaskets 70 may be made of another material that is sufficiently soft to avoid damaging the end 56 and 58 of the rigid connecting tube 30. The sealing gasket 70 may in general comprise either an electrically insulating material or an electrically conductive material.

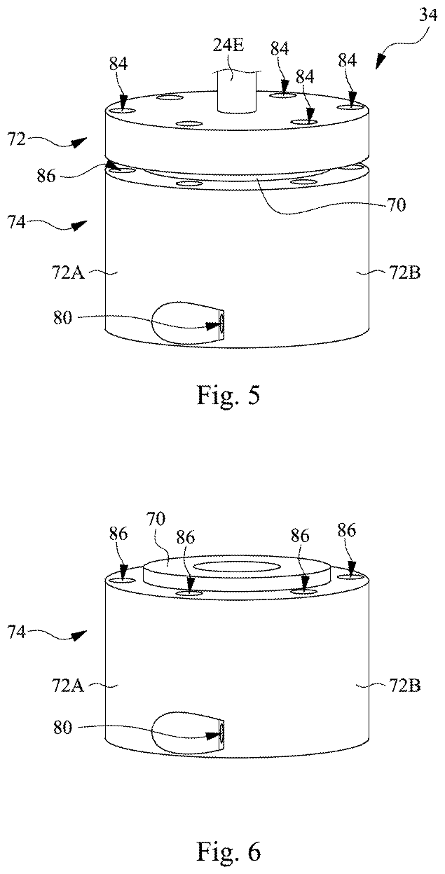

With reference to FIGS. 5 and 6, a nonlimiting illustrative embodiment of the output gas coupling 34 is shown without the fasteners 76 (FIG. 5), and further without the first clamp piece 72 (FIG. 6). As previously noted, the input and output gas couplings 32 and 34 have the same construction in the illustrative examples, and accordingly the gas coupling of FIGS. 5 and 6 could also represent the input gas coupling by inverting it. Starting with particular reference to FIG. 5, the first clamp piece 72 can suitably be a single piece, for example formed as a plate of metal with a central opening within which the end 24E of the output metal gas line 24 is welded or otherwise secured in gas tight fashion.

On the other hand, the unitary construction of the sapphire connecting tube 30 is accommodated in the embodiment of FIGS. 5 and 6 by forming the second clamp piece 74 as two pieces 72A and 72B that are secured together around the second end 58 of the sapphire connecting tube 30 and secured around it by bolts or other fasteners (e.g. screws) 80 (also diagrammatically shown and labeled in FIG. 4). As seen in the sectional views of the input and output gas couplings 32 and 34 shown in FIG. 4, the first end 56 and the second end 58 of the connecting tube 30 each have an annular seat 82 into which the second clamp piece 74 engages to secure the second clamp pieces 74 of the respective gas couplings 32 and 34 with the respective ends 56 and 58 of the connecting tube 30. This is merely one illustrative example of one way to secure the second clamp piece 74 with the end of the sapphire connecting tube 30, and other approaches are contemplated.

In FIGS. 5 and 6 the fasteners 76 are omitted; however, the openings 84 of the first clamp piece 72 (see FIG. 5) and openings 86 of the second clamp piece 74 (see FIGS. 5 and 6) with which the fasteners 76 engage are shown. In the illustrative embodiment, the openings 84 of the first clamp piece 72 may suitably be through holes (optionally with countersinking to accommodate a bolt head), while the openings 86 of the second clamp piece 74 are suitably threaded holes. Each fastener 76 then passes through a through hole 84 of the first clamp piece 72 and threads into the aligned threaded opening 86 of the second clamp piece 74 to fasten the clamp pieces 72 and 74 together. The illustrative embodiment of FIGS. 5 and 6 includes six through hole 84 of the first clamp piece 72 and six respectively aligned threaded opening 86 of the second clamp piece 74 arranged at 60-degree intervals around the circumference of the gas coupling to provide symmetric and distributed clamping force; however, a different number of fasteners is contemplated.

The first and second clamp pieces 72 and 74 can be made of any suitably sturdy material, such as metal, hard plastic, or so forth. The first and second clamp pieces 72 and 74 do not need to be electrically insulating (e.g., they can be made of metal).

The disclosed gas couplings 32 and 34 provide numerous advantages. They are effective for providing a gas tight seal between the metal line and the ends of the sapphire or other electrically insulating connecting tube 30. The gas couplings 32 and 34 also can be reused, that is, connected and disconnected repeatedly, with at most replacing the (typically low-cost) PTFE sealing gasket 70 (as it will likely be deformed by the compression applied by the compression clamp 72, 74 and hence a reused sealing gasket may be prone to leakage). The gas couplings 32 and 34 can also be constructed with mostly off-the-shelf components, except that the second clamp piece 74 which engages the end of the connecting tube 30 may benefit from having a customized shape to effectively engage the annular seat 82 of the end of the connecting tube 30. The gas couplings 32 and 34 are also rigid, thus further facilitating robustness of the gas interface 22 against seismic events.

With returning reference to FIGS. 1-3, the illustrative gas interface 22 includes a single connecting tube 30 suitable for providing flow transfer of one process gas from an input metal gas line 20 at electrical ground (0V) potential to an output metal gas line 24 at a high voltage while maintaining electrical isolation of the input metal gas line 20 from the output metal gas line 24. It will be appreciated the gas interface 22 can instead include two, three, four, or more connecting tubes 30 of analogous construction to provide flow transfer of two, three, four, or more different process gases.

In another variant embodiment, it is contemplated to include redundant connecting tubes 30 and suitable pneumatically or electrically actuated valving to switch flow of a process gas from one connecting tube 30 to another connecting tube 30. For example, such redundancy can provide a redundant flow path for a toxic process gas such as phosphine or arsine-if the input gas coupling 32 or output gas coupling 34 of the utilized connecting tube 30 develops a leak (as detected by the sensor 40) then the flow path can be switched to the redundant connecting tube 30 to enable continued operation of the semiconductor processing tool 10.

In the following, some further embodiments are described.

In a nonlimiting illustrative embodiment, a gas interface includes a connecting tube which is electrically insulating, an input metal gas line, an output metal gas line, an input gas coupling providing a gas-tight seal between an end of the input metal gas line and a first end of the connecting tube, and an output gas coupling providing a gas-tight seal between an end of the output metal gas line and a second end of the connecting tube. The input gas coupling includes: a sealing gasket disposed between the end of the input metal gas line and the first end of the connecting tube; and a compression clamp including a first clamp piece engaging the end of the input metal gas line and a second clamp piece engaging the first end of the connecting tube, the first and second clamp pieces being secured together to compress the sealing gasket between the end of the input metal gas line and the first end of the connecting tube. The output gas coupling includes: a sealing gasket disposed between the end of the output metal gas line and the second end of the connecting tube; and a compression clamp including a first clamp piece engaging the end of the output metal gas line and a second clamp piece engaging the second end of the connecting tube, the first and second clamp pieces being secured together to compress the sealing gasket between the end of the output metal gas line and the second end of the connecting tube.

In a nonlimiting illustrative embodiment, a method of operating a semiconductor processing tool includes: flowing a process gas from an input metal gas line that is electrically grounded to an output metal gas line via a connecting tube which is electrically insulating, wherein couplings between the metal gas lines and the connecting tube are sealed with gas couplings, each gas coupling including a sealing gasket and a clamp compressing the sealing gasket between an end of the respective metal gas line and a corresponding end of the connecting tube; delivering the process gas to the semiconductor processing tool via the output metal gas line; and performing at least one operation at the semiconductor processing tool that utilizes both the process gas delivered to the process tool via the output metal gas line and an electrical voltage of at least 2 kilovolts.

In a nonlimiting illustrative embodiment, an ion implantation system includes an ion implanter connected to receive a process gas from an output metal gas line, and a gas interface. The gas interface includes a housing which is electrically insulating, a connecting tube which is electrically insulating and which is disposed in the housing and secured to the housing, an input gas coupling, and an output gas coupling. The input gas coupling is disposed in the housing and provides a gas-tight seal between an end of an input metal gas line and a first end of the connecting tube. The input gas coupling includes a sealing gasket disposed between the end of the input metal gas line and the first end of the connecting tube, and a compression clamp compressing the sealing gasket between the end of the input metal gas line and the first end of the connecting tube. The output gas coupling is disposed in the housing and provides a gas-tight seal between an end of the output metal gas line and a second end of the connecting tube. The output gas coupling includes a sealing gasket disposed between the end of the output metal gas line and the second end of the connecting tube, and a compression clamp compressing the sealing gasket between the end of the output metal gas line and the second end of the connecting tube.

In a nonlimiting illustrative embodiment, a process gas is flowed from an input metal gas line that is electrically grounded to an output metal gas line via a connecting tube which is electrically insulating. Couplings between the metal gas lines and the connecting tube are sealed with gas couplings. Each gas coupling includes a sealing gasket, and a clamp compressing the sealing gasket between an end of the respective metal gas line and a corresponding end of the connecting tube. The process gas is delivered to a semiconductor processing tool via the output metal gas line. At least one operation is performed at the semiconductor processing tool that utilizes both the process gas delivered to the process tool via the output metal gas line and an electrical voltage of at least 2 kilovolts. The connecting tube may be sapphire. The sealing gaskets may be polytetrafluoroethylene (PTFE) sealing gaskets.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A gas interface comprising:
a connecting tube which is electrically insulating;
an input metal gas line;
an output metal gas line;
an input gas coupling providing a gas-tight seal between an end of the input metal gas line and a first end of the connecting tube, the input gas coupling including:
a sealing gasket disposed between the end of the input metal gas line and the first end of the connecting tube, and
a compression clamp including a first clamp piece engaging the end of the input metal gas line and a second clamp piece engaging the first end of the connecting tube, the first and second clamp pieces being secured together to compress the sealing gasket between the end of the input metal gas line and the first end of the connecting tube; and
an output gas coupling providing a gas-tight seal between an end of the output metal gas line and a second end of the connecting tube, the output gas coupling including:
a sealing gasket disposed between the end of the output metal gas line and the second end of the connecting tube, and
a compression clamp including a first clamp piece engaging the end of the output metal gas line and a second clamp piece engaging the second end of the connecting tube, the first and second clamp pieces being secured together to compress the sealing gasket between the end of the output metal gas line and the second end of the connecting tube.

2. The gas interface of claim 1, wherein the connecting tube is a sapphire connecting tube.

3. The gas interface of claim 2, wherein the sealing gaskets of the input and output gas couplings are polytetrafluoroethylene (PTFE) sealing gaskets.

4. The gas interface of claim 2, wherein the sealing gaskets of the input and output gas couplings comprise a material that is softer than sapphire.

5. The gas interface of claim 1, further comprising:
a housing which is electrically insulating, wherein the connecting tube, the input gas coupling, and the output gas coupling are disposed within the housing.

6. The gas interface of claim 5, wherein the housing includes a purge gas inlet and a purge gas outlet for flowing a purge gas through the housing.

7. The gas interface of claim 5, wherein the connecting tube is secured to the housing to form an earthquake-resistant rigid assembly.

8. The gas interface of claim 1, wherein the connecting tube is a straight tube having a length of at least 15 cm.

9. A semiconductor processing system comprising:
a semiconductor processing tool configured to operate at a voltage of at least 2 kilovolts; and
a gas interface as set forth in claim 5, wherein the input metal gas line connects with an electrically grounded gas supply and the output metal gas line connects with the semiconductor processing tool.

10. The semiconductor processing system of claim 9, wherein the housing of the gas interface is gas-tight and includes a purge gas inlet and a purge gas outlet for flowing a purge gas through the housing, the semiconductor processing system further comprising:
an exhaust connected to receive the purge gas after passing through the purge gas outlet; and
a gas monitoring system operatively coupled with the exhaust and configured to detect leakage of a toxic gas into the purge gas.

11. The semiconductor processing system of claim 9, wherein the semiconductor processing tool comprises an ion implanter.

12. A method of operating a semiconductor processing tool, the method comprising:
flowing a process gas from an input metal gas line that is electrically grounded to an output metal gas line via a connecting tube which is electrically insulating, wherein couplings between the metal gas lines and the connecting tube are sealed with gas couplings, each gas coupling including a sealing gasket and a clamp compressing the sealing gasket between an end of the respective metal gas line and a corresponding end of the connecting tube;
delivering the process gas to the semiconductor processing tool via the output metal gas line; and
performing at least one operation at the semiconductor processing tool that utilizes both the process gas delivered to the process tool via the output metal gas line and an electrical voltage of at least 2 kilovolts.

13. The method of claim 12, wherein the connecting tube is a sapphire connecting tube.

14. The method of claim 13, wherein the sealing gaskets of the gas couplings are polytetrafluoroethylene (PTFE) sealing gaskets.

15. The method of claim 12, wherein the connecting tube and the gas couplings are disposed in a housing which is electrically insulating, and the method further comprises:
flowing a purge gas through and out of the housing; and
monitoring the purge gas flowing out of the housing using a gas monitoring system configured to detect leakage of a toxic gas into the purge gas.

16. The method of claim 12, wherein the process gas includes at least one of phosphine and/or arsine.

17. The method of claim 12, wherein the semiconductor processing tool comprises an ion implanter, and the at least one operation performed at the ion implanter includes:
performing ion implantation by ionizing the process gas delivered to the ion implanter via the output metal gas line into an ionized process gas and accelerating ions of the ionized process gas using an electrostatic accelerator operating at the electrical voltage of at least 2 kilovolts.

18. An ion implantation system comprising:
an ion implanter connected to receive a process gas from an output metal gas line; and
a gas interface including:
a housing which is electrically insulating;
a connecting tube which is electrically insulating and which is disposed in the housing and secured to the housing;
an input gas coupling disposed in the housing and providing a gas-tight seal between an end of an input metal gas line and a first end of the connecting tube, the input gas coupling including a sealing gasket disposed between the end of the input metal gas line and the first end of the connecting tube, and a compression clamp compressing the sealing gasket between the end of the input metal gas line and the first end of the connecting tube; and
an output gas coupling disposed in the housing and providing a gas-tight seal between an end of the output metal gas line and a second end of the connecting tube, the output gas coupling including a sealing gasket disposed between the end of the output metal gas line and the second end of the connecting tube, and a compression clamp compressing the sealing gasket between the end of the output metal gas line and the second end of the connecting tube.

19. The ion implantation system of claim 18, wherein the connecting tube of the gas supply box is a sapphire connecting tube, and the gaskets of the input and output gas couplings are polytetrafluoroethylene (PTFE) sealing gaskets.

20. The ion implantation system of claim 18, further comprising:
a gas bottle connected with the input metal gas line, the gas bottle containing arsine or phosphine.
